(19) United States
(12) Patent Application Publication
(10) Pub. No.: US 2018/0098422 A1
(43) Pub. Date: Apr. 5, 2018

(54) TRANSPARENT CONDUCTIVE FILM AND DISPLAY DEVICE

(71) Applicant: KANEKA CORPORATION, Osaka (JP)

(72) Inventors: Takashi Kuchiyama, Osaka (JP); Kenji Yamamoto, Osaka (JP)

(73) Assignee: KANEKA CORPORATION, Osaka (JP)

(21) Appl. No.: 15/562,267

(22) PCT Filed: Apr. 1, 2016
(86) PCT No.: PCT/JP2016/060959

§ 371 Date: Sep. 27, 2017

(30) Foreign Application Priority Data
Apr. 6, 2015 (JP) 2015-077871

(51) Int. Cl. H05K 1/02; H01L 31/0224; H01L 31/18; H01L 51/00; H01L 51/44

(52) U.S. Cl. CPC H05K 1/0274; H01L 31/022466; H05K 2201/0108; H01L 51/0023; H01L 51/445; H01L 31/1884

(57) ABSTRACT

A transparent conductive film is disclosed. It includes a transparent film base and a transparent electrode layer comprising a transparent conductive oxide layer and a patterned metal layer stacked in contact with each other. The maximum layer thickness of the transparent electrode layer is 300 nm. The metal layer has a metal pattern width of 1 μm or more and 8 μm or less, and the metal pattern coverage ratio of 0.4% or more and 3.2% or less. It is preferable that the metal layer has a layer thickness of 50 nm or more and 250 nm or less. It is also preferable that the pattern shape of the metal layer is of stripes, mesh, dots or the like.

### TECHNICAL FIELD

The present invention relates to a transparent conductive film and a display device.

### BACKGROUND ART

In a transparent electrode to be used in a display device such as a touch panel or a display, control of sheet resistance as an electrical property is important. Since sheet resistance is in inverse proportional to layer thickness, sheet resistance can be reduced by increasing the layer thickness of the transparent electrode. On the other hand, when the thickness is increased, absorption of light by a transparent electrode increases thereby deteriorate optical property (transparency).

Various transparent electrodes have been developed with consideration given to a balance between electrical properties and optical properties. For example, Patent Document 1 discloses a transparent conductive film for an organic EL device in which a transparent conductive material layer is provided so as to cover a metal stripe line having a line width of 0.3 to 20 mm.

### PRIOR ART DOCUMENT

### Patent Document

Patent Document 1: International Publication No. WO 2013/035283

### SUMMARY OF THE INVENTION

### Problems to be Solved by the Invention

Further reduction of resistance of a transparent electrode has been required for in-plane potential uniformity of an electrode for a display, improvement of a response speed of a capacitance touch panel, and so on. As disclosed in Patent Document 1, combination of a transparent conductive layer and a patterned metal layer may contribute to a reduction of resistance. However, a metal layer has light reflectivity, and therefore it is necessary to design a pattern shape being hardly visible for maintaining transparency. A transparent conductive film with a transparent conductive layer provided on a film base may be warped due to imbalance of stress on front and back sides of the film.

In view of the situations described above, an object of the present invention is to provide a transparent conductive film which has both low resistance and high transparency and which is inhibited from being warped.

### Means for Solving the Problems

A transparent conductive film of the present invention includes a transparent film base, and a transparent electrode layer provided on the transparent film base. In the transparent electrode layer, a transparent conductive oxide layer and a patterned metal layer are stacked in contact with each other. The transparent electrode layer has a maximum layer thickness of 300 nm or less. The metal layer has a metal pattern width of 1 μm or more and 8 μm or less, and a metal pattern coverage ratio of 0.4% or more and 3.2% or less. Preferably, the metal layer has a layer thickness of 50 nm or more and 250 nm or less. The pattern shape of the metal layer is preferably a stripe shape, a mesh shape, a dot shape or the like.

Examples of the stacking configuration of the transparent conductive oxide layer and the metal layer in the transparent conductive layer include a configuration in which the transparent conductive oxide layer and the metal layer are provided in this order from the transparent film base side (first stacking structure); a configuration in which the metal layer and the transparent conductive oxide layer are provided in this order from the transparent film base side (second stacking structure); and a configuration in which the metal layer is encapsulated in the transparent conductive oxide layer (third stacking structure).

The transparent conductive oxide layer is preferably a crystalline film mainly composed of indium oxide. The metal layer is preferably a copper layer or a copper alloy layer.

The transparent conductive film of the present invention can be used in a display device such as a display or a touch panel. In such a device, it is preferable that the transparent conductive film is used over an area occupying 80% or more of a display region.

### Effect of the Invention

The present invention provides a transparent conductive film which has both reduced resistance and high transparency and which is inhibited from being warped.

### BRIEF DESCRIPTION OF THE DRAWINGS

FIG. 1 is a sectional view of a transparent conductive film of one embodiment (first stacking structure).

FIG. 2 is a view showing an example of a pattern shape of a metal layer, where FIG. 2A shows a stripe shape, FIG. 2B shows a mesh shape, and FIG. 2C shows a dot shape.

FIG. 3 is a graph showing a relationship between the metal layer coverage ratio and sheet resistance where the transparent conductive oxide layer and the metal layer form parallel resistance and series resistance.

FIG. 4 is a sectional view of a transparent conductive film of one embodiment (second stacking structure).

FIG. 5 is a sectional view of a transparent conductive film of one embodiment (third stacking structure).

FIG. 6 is a plan view of a display device.

### DESCRIPTION OF EMBODIMENTS

Embodiments of the present invention will be described below, but the present invention is not limited to these embodiments. The dimensional relation in each drawing is appropriately changed for the sake of clarification and simplification of the drawing, and an actual dimensional relation is not reflected in the drawing.

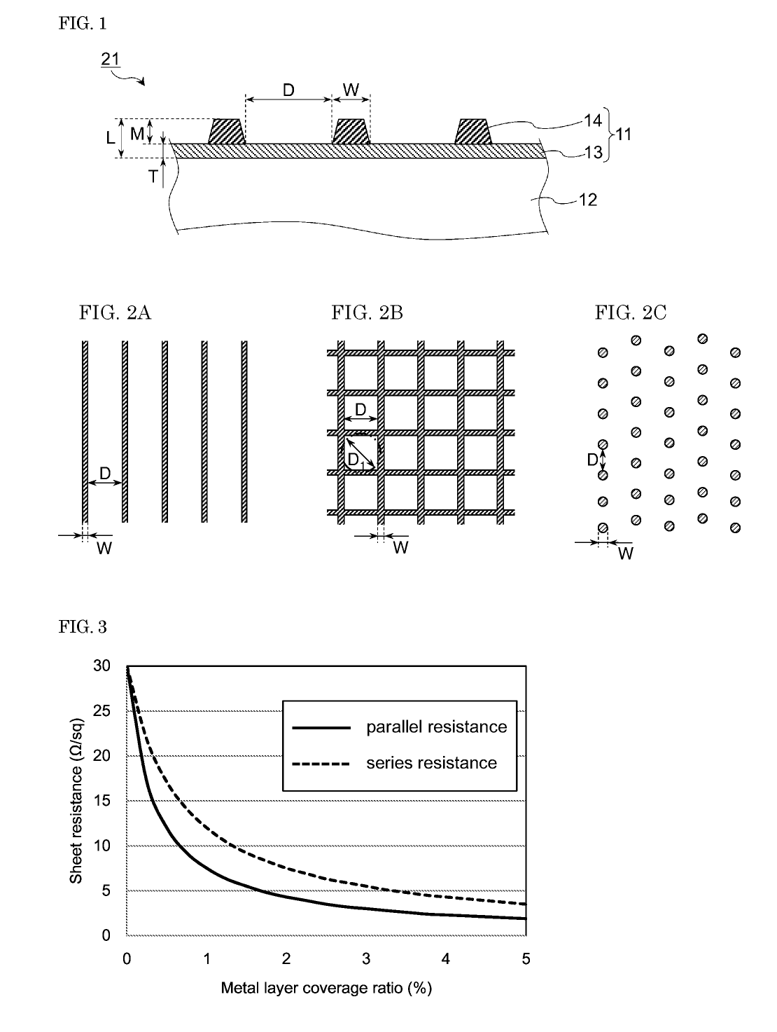

FIG. 1 is a sectional view of a transparent conductive film according to one embodiment of the present invention. A transparent conductive film 21 includes at least a transparent film base 12 and a transparent electrode (transparent electrode layer) 11. The transparent electrode layer 11 includes a transparent conductive oxide layer 13 and a metal layer 14, which are stacked in contact with each other. The metal layer 14 has a pattern shape. In the stacking configuration (sometimes referred to as a first stacking structure) of the transparent electrode layer 11 shown in FIG. 1, the transparent conductive oxide layer 13 as a lower layer and the metal layer 14 as an upper layer are stacked in contact with each other.

The transparent film base 12 is a stuff serving as a base (basis) for the transparent conductive film, and may be colorless and transparent in at least a visible light region. The transparent film base 12 may have any thickness, and the thickness is preferably 10 μm or more and 400 μm or less, more preferably 20 μm or more and 200 or less. When the thickness is within the above-mentioned range, the transparent film base, and the transparent conductive film obtained using the transparent film base have sufficient durability and moderate flexibility. When the thickness of the transparent film base is within the above-mentioned range, a transparent electrode layer can be deposited by a roll-to-roll method, and therefore productivity of the transparent conductive film can be improved.

Examples of the material of the transparent film base 12 include polyester resins such as polyethylene terephthalate (PET), polybutylene terephthalate (PBT) and polyethylene naphthalate (PEN); cycloolefin-based resins; polycarbonate resins; polyimide resins; and cellulose-based resins. Among them, polyethylene terephthalate or a cycloolefin-based resin is inexpensive and excellent in transparency, and is therefore preferably used as the transparent film base 12. As the transparent film base 12, one in which molecules are oriented by biaxial stretching to improve mechanical properties such as a Young's modulus and heat resistance is preferably used. Warpage of the transparent conductive film may be reduced by using a low-heat shrinkage film in which stress strain is relaxed by adjustment of conditions for stretching or heating after stretching, the heat shrinkage ratio is reduced to about 0.2% or less, and the heat shrinkage initiation temperature is increased.

A functional layer such as an optical adjustment layer, an antireflection layer, an antiglare layer, an easily adhesive layer, a stress buffer layer, a hard coat layer, a slippery layer, an antistatic layer, a crystallization acceleration layer, a crystallization rate adjustment layer or a durability improvement layer may be provided on one surface or both surfaces of the transparent film base 12. For example, when a hard coat layer is provided on a surface of the transparent film base, the thickness of the hard coat layer is preferably about 1 to 10 μm, more preferably 3 to 8 μm, further preferably 5 to 8 μm. The material of the hard coat layer is not particularly limited, and examples thereof include urethane-based resins, acryl-based resins and silicone-based resins. A hard coat layer may be formed by applying and curing a hard coat material.

The transparent conductive film 21 includes the transparent electrode layer 11 on the transparent film base 12. The transparent electrode layer may be provided on both surfaces of the transparent film base. In general, the transparent electrode layer is provided only on one surface of the base.

The transparent conductive oxide layer 13 may be a single layer or may have multiple layers. The transparent conductive oxide layer 13 includes an oxide mainly composed of, for example, indium oxide. The content of indium oxide in the transparent conductive oxide layer 13 is preferably 87.5% by weight or more and 99% by weight or less, more preferably 90% by weight or more and 97% by weight or less, further preferably 90% by weight or more and 95% by weight or less. The transparent conductive oxide layer 13 contains a doped impurity for imparting conductivity by increasing carrier density in the film. Examples of the doped impurity for indium oxide include tin oxide, zinc oxide, titanium oxide, tungsten oxide and cerium oxide. For example, in indium tin oxide (ITO), tin oxide is contained as a doped impurity. The content of the doped impurity in the transparent conductive oxide layer 13 is preferably 1% by weight or more and 12.5% by weight or less, more preferably 3% by weight or more and 10% by weight or less, further preferably 5% by weight or more and 10% by weight or less.

The carrier density of the transparent conductive oxide layer 13 is more preferably 4×10²⁰ cm⁻³ or more and 9×10²⁰ cm⁻³ or less, more preferably 6×10²⁰ cm⁻³ or more and 8×10²⁰ cm⁻³ or less. For example, when the doped impurity concentration is adjusted to fall within the aforementioned range, a transparent conductive oxide layer having the above-mentioned carrier density is obtained. When the carrier density is in the above-mentioned range, resistivity of the transparent conductive oxide layer 13 is easily reduced. For example, the resistivity of the transparent conductive oxide layer 13 is easily reduced to 3.5×10⁻⁴ Ωcm.

The transparent conductive oxide layer 13 is preferably a crystalline film mainly composed of indium oxide, and the crystallinity thereof is preferably 90% or more, more preferably 95% or more. When the transparent conductive oxide layer 13 is a crystalline film having a high crystallinity, light absorption is small, so that transparency is improved, and a resistance change caused by an environmental change etc. tends to be suppressed. When the crystallinity is within the above-mentioned range, a film quality change associated with an environmental change is small, and therefore adhesion between the transparent conductive oxide layer 13 and the metal layer 14 tends to be improved. The crystallinity is determined from a ratio of an area occupied by crystal grains in an observation visual field in microscopic observation.

In the first stacking structure shown in FIG. 1, the patterned metal layer 14 is provided on the transparent conductive oxide layer 13. As a material of the metal layer 14, a metal having a resistivity smaller than that of the transparent conductive oxide is used. The resistivity of the metal layer 14 is preferably 1×10⁻⁵ Ωcm or less, and examples of the metal include gold, platinum, iron, copper, silver, aluminum, chromium, cobalt, silver and alloys including any of these metals. Among them, silver, silver alloys, copper and copper alloys are preferable. Copper and copper alloys are especially preferable because they have a small resistivity, are inexpensive, and are easily patterned by etching etc. The copper alloy is preferably an alloy mainly composed of copper, i.e. an alloy containing 50% or more of copper in terms of a material ratio to the whole metal layer 14.

When the metal layer 14 including a high conductivity material such as copper is provided in a pattern shape in such a manner that the metal layer 14 is in contact with the plane transparent conductive oxide layer 13, the metal layer 14 serves as a relay point for feeding in-plane electricity in the transparent electrode layer 11. As a result, resistance of the transparent electrode layer 11 can be reduced. The metal layer 14 that is provided to serve as a relay point in feeding electricity to the transparent electrode layer 11, i.e., serve to assist in collection and diffusion of conductive carriers, is not required to be fully physically integrated. The metal layer 14 may be an assembly of separated metal thin-film layer pieces (physically separated metal thin-film layer pieces are sometimes referred to as “pattern pieces”).

The pattern shape of the metal layer 14 is not particularly limited, and examples thereof include a stripe pattern as shown in FIG. 2A, a mesh pattern as shown in FIG. 2B, and a dot pattern as shown in FIG. 2C. The width W of the pattern piece of the metal layer is 8 μm or less. When the pattern shape of the metal layer is a stripe shape or a mesh shape, i.e., the metal piece is linear, the line width corresponds to the metal pattern width W. When the metal piece has a dot shape, the dot diameter corresponds to the metal pattern width W. The metal pattern width is preferably 1 μm or more from the viewpoint of ease of pattern formation, etc.

The metal pattern coverage ratio is 0.4% or more and 3.2% or less. When the width of the metal pattern is 8 μm or less, and the metal pattern coverage ratio is 3.2% or less, the metal pattern is hardly visible, so that transparency of the transparent electrode layer 11 can be secured. When the metal pattern coverage ratio is 3.2% or less, stress at the interface between the metal layer 14 and the transparent conductive oxide layer 13 is relaxed, so that warpage of transparent conductive film tends to be suppressed. When the metal pattern coverage ratio is 0.4% or more, the function of the metal layer 14 as an auxiliary electrode for the transparent conductive oxide layer 13 is enhanced, so that sheet resistance can be reduced without excessively increasing the maximum layer thickness L of the transparent electrode layer 11. In other words, the layer thickness L required for achieving desired sheet resistance is small, and therefore stress at the interface between the transparent film base 12 and the transparent electrode layer 11 is small, so that warpage of the transparent conductive film can be suppressed.

The metal pattern coverage ratio is preferably 0.5% or more and 3.0% or less, more preferably 0.8% or more and 2.7% or less, further preferably 1.0% or more and 2.5% or less. The metal pattern coverage ratio is calculated from the following equation:

coverage ratio (%)=area of metal layer 14/area of transparent electrode layer 11.

The area of the metal layer is determined from microscopic observation. When the transparent conductive film is used in a display device 31 having a bezel 33 on the peripheral edge as shown in FIG. 6, the coverage ratio may be determined in a display reference area at the center of a display region R_{A}. When the transparent conductive film is used in a capacitance touch panel, the transparent electrode layer 11 is patterned in, for example, a stripe shape or square shape having a width of several mm. In this case, coverage ratio may be determined in a region provided with the transparent electrode layer.

The distance D between pattern pieces of the metal layer is preferably 30 μm or more and 2000 μm or less for ensuring that both the pattern width and the coverage ratio of the metal layer 14 are each within the above-mentioned range.

When the pattern of the metal layer 14 has a stripe shape, the distance between metal lines corresponds to the distance D between pattern pieces of the metal layer (see FIG. 2A). In a pattern having a stripe shape, auxiliary electrode lines connecting a plurality of metal lines may be provided in a direction orthogonal to the extending direction of stripe lines. When auxiliary electrode lines are provided, the width of the auxiliary electrode line is preferably 8 μm or less. The distance between auxiliary electrode lines in a direction orthogonal to the extending direction of the stripe line is not less than 3 times of the distance D between stripe lines. When distance between auxiliary electrode lines is less than 3 times of the distance between stripe line, the pattern shape is regarded as a mesh shape.

When the pattern of the metal layer 14 has a mesh shape, the distance between metal lines corresponds to the distance D between pattern pieces of the metal layer (see FIG. 2B). The shape of a mesh opening is not limited to a square, and may be a triangle, a rectangle, a rhomboid, a parallelogram, a trapezoid, a honeycomb shape or the like. When metal lines are arranged in non-parallel, so that the distance between pattern pieces cannot be directly determined, the circular-equivalent diameter D₁ of the opening may be defined as a distance between pattern pieces.

When the pattern of the metal layer 14 has a dot shape, the distance between dots closest to each other corresponds to the distance D between pattern pieces of the metal layer (see FIG. 2C). Dots may be arranged in a grid shape or a zigzag shape, or randomly arranged. The distance between dots may be constant or random. The distance between dots may vary depending on the direction of arrangement of dots.

As described above, the sheet transparent conductive oxide layer 13 and the patterned metal layer 14 are stacked in contact with each other, so that sheet resistance can be reduced without excessively increasing the thickness while transparency of the transparent electrode layer 11 is secured. Thus, warpage of the transparent conductive film due to stress at the interface is suppressed.

Sheet resistance of the transparent electrode layer can be reduced because the metal layer 14 serves as a relay point for feeding in-plane current in the transparent electrode layer even when the metal layer 14 is in the form of separated pattern pieces as described above. This is associated with a configuration in which the transparent conductive oxide layer 13 and the patterned metal layer 14 are stacked in contact with each other, and therefore act as parallel resistance to an in-plane current in the transparent electrode layer.

A transparent conductive material such as a transparent conductive oxide is provided so as to fill gaps in the pattern of the metal layer, and when the transparent conductive oxide layer is not provided on and under the metal layer, an equivalent circuit formed by the metal layer and the transparent conductive material forms series resistance. In this case, resistance R_{S} of the transparent electrode layer is expressed by a sum of resistance R_{M} of the metal layer and resistance R_{T} of the transparent conductive material as in the following equation.

R_{S}=R_{T}+R_{M}

When the transparent conductive oxide layer 13 and the metal layer 14 are stacked, and the transparent conductive oxide layer 13 is in contact with the lower surface and/or upper surface of the metal layer, an equivalent circuit formed by these layers form parallel resistance. In this case, resistance R_{P} of the transparent electrode layer 11 is expressed by a reciprocal of a sum of a reciprocal of resistance R_{M} of the metal layer and a reciprocal of resistance R_{T} of the transparent conductive oxide layer as in the following equation.

$${R}_{P} = \frac{1}{\frac{1}{{R}_{T}} + \frac{1}{{R}_{M}}}$$

FIG. 3 shows graphs in which the abscissa represents a metal layer coverage ratio, and the ordinate represents sheet resistance of the transparent electrode layer where the transparent conductive oxide layer and the metal layer form parallel resistance and series resistance. As shown in FIG. 3, the transparent conductive oxide layer 13 and the metal layer 14 are stacked, and when these layers form parallel resistance, sheet resistance is small. It is apparent that particularly when the metal layer coverage ratio is in a range of about 0.8 to 3.2%, there is a large difference between series resistance R_{S} and parallel resistance R_{P}.

For securing transparency and reducing resistance of the transparent electrode layer, and suppressing warpage of the transparent conductive film, it is preferable that the thickness of the transparent electrode layer is within a specific range in addition that line width and the coverage ratio of the metal pattern are each set to be within the above-mentioned range. The maximum layer thickness L of the transparent electrode layer 11 is preferably 300 nm or less, more preferably 270 nm or less, further preferably 240 nm or less.

The maximum layer thickness L of the transparent electrode layer 11 corresponds to a distance along a normal line direction of the base surface between the surface of the transparent film base 12 and the surface of the transparent electrode layer 11 at a metal layer 14-formed portion. In the first stacking structure shown in FIG. 1, the sum of the layer thickness T of the transparent conductive oxide layer 13 and the layer thickness M of the metal layer pattern piece 14 corresponds to the maximum layer thickness L of the transparent electrode layer. When the maximum layer thickness of the transparent electrode layer is within the above-mentioned range, warpage due to a stress difference between the front side and the back side of the transparent film base 12 tends to be suppressed. The maximum layer thickness L of the transparent electrode layer 11 is preferably 80 nm or more for securing conductivity of the transparent electrode layer.

The layer thickness M of the patterned metal layer 14 is preferably 50 nm or more and 250 nm or less, more preferably 100 nm or more and 220 nm or less, further preferably 120 nm or more and 200 nm or less. When the layer thickness of the metal layer 14 is within the above-mentioned range, warpage at the interface is suppressed, and the function of the metal layer as an auxiliary electrode is secured, so that sheet resistance of the transparent electrode layer can be reduced.

The layer thickness T of the transparent conductive oxide layer 13 is preferably 10 nm or more and 120 nm or less, more preferably 12 nm or more and 70 nm or less, further preferably 15 nm or more and 50 nm or less. Since the transparent conductive oxide layer is formed in a sheet shape, stress at the interface easily occurs in the transparent conductive oxide layer than in the patterned metal layer 14. When the layer thickness of the transparent electrode layer is within the above-mentioned range, warpage due to stress can be suppressed while the transparent electrode layer has both transparency and conductivity.

The ratio M/T of the layer thickness T and the transparent conductive oxide layer 13 and the layer thickness M of the metal layer 14 is preferably 1 or more and 10 or less, more preferably 1.5 or more and 7 or less, further preferably 2 or more and 5 or less. When the ratio of the layer thickness T and the layer thickness M is within the above-mentioned range, warpage of the transparent conductive film is easily suppressed, and an effect of reducing sheet resistance of the transparent electrode layer 11 by the metal layer 14 is easily obtained.

The stacking configuration of the transparent conductive oxide layer 13 and the metal layer 14 in the transparent electrode layer 11 is not limited to the configuration shown in FIG. 1 as long as the transparent conductive oxide layer 13 and the metal layer 14 are stacked in contact with each other in a surface parallel to the base surface.

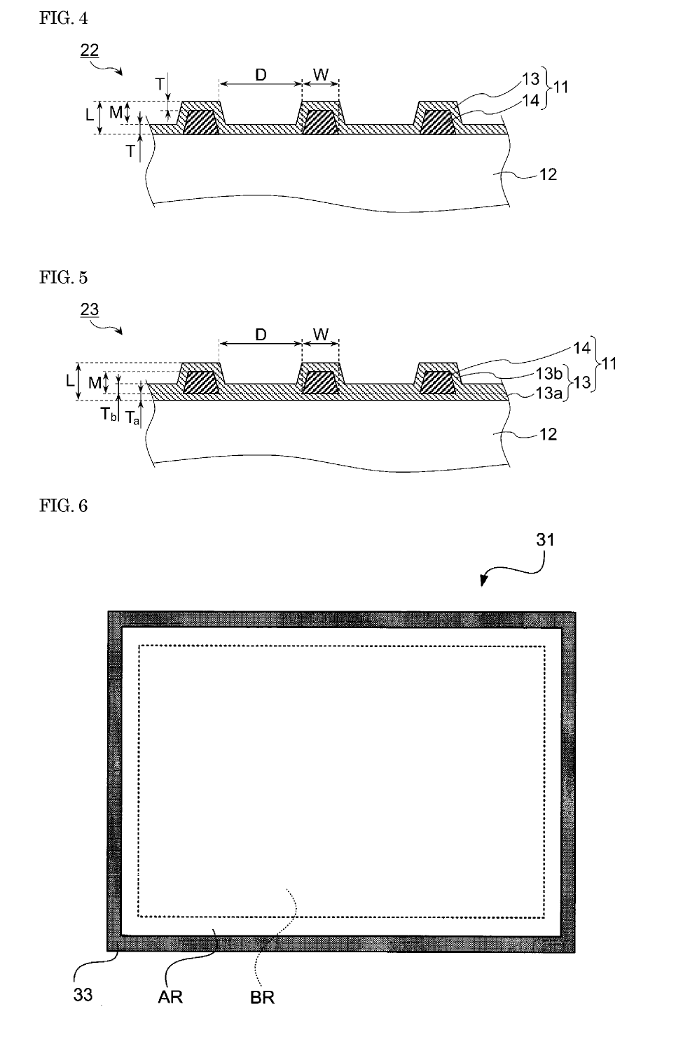

For example, as shown in FIG. 4, the patterned metal layer 14 may be provided on upper side of the transparent film base 12, and the transparent conductive oxide layer 13 may be provided on upper side of the patterned metal layer (pattern pieces) 14 and the transparent film base 12 exposed between the pattern pieces 14 (this stacking configuration is sometimes referred to as a second stacking structure). In the second stacking structure, the metal layer 14 as a lower layer and the transparent conductive oxide layer 13 as an upper layer are stacked in contact with each other in the transparent electrode layer 11.

As shown in FIG. 5, the patterned metal layer 14 may be encapsulated in the transparent conductive oxide layer 13 (this stacking configuration is sometimes referred to as a third stacking structure). In the third stacking structure, the patterned metal layer (pattern pieces) 14 is stacked on a lower transparent conductive oxide layer 13a provided on the transparent film base 12. Further, an upper transparent conductive oxide layer 13b is provided on upper side of the pattern pieces 14 and the lower transparent conductive oxide layer 13a exposed between the patter pieces 14. In this way, in the third stacking structure, the patterned metal layer 14 is provided between the lower transparent conductive oxide layer 13a and the upper transparent conductive oxide layer 13b, so that the metal layer 14 is encapsulated in the transparent conductive oxide layer 13 in such a manner that the metal layer 14 is in contact with the transparent conductive oxide layer 13.

In the second stacking structure and the third stacking structure, the transparent electrode layer 11 has both transparency and reduced resistance, and warpage of the transparent conductive film can be suppressed when the pattern width and the coverage ratio of the metal layer are each within a specific range as in the case of the first stacking structure. Preferably, the maximum layer thickness L of the transparent electrode layer, the layer thickness T of the transparent conductive oxide layer 13 and the layer thickness M of the metal layer 14 are each set to be within the same range as in the case of the first stacking structure.

The maximum layer thickness L of the transparent electrode layer 11 in the second stacking structure corresponds to a distance along a normal line direction of the base surface between the surface of the transparent film base 12 and the surface of the transparent conductive oxide layer 13 at a metal layer 14-formed portion. The layer thickness T of the transparent conductive oxide layer 13 in the third stacking structure is the sum of the layer thickness Tₐ of the lower transparent conductive oxide layer 13a and the layer thickness T_{b} of the upper transparent conductive oxide layer 13b. The maximum layer thickness L of the transparent electrode layer 11 in the third stacking structure corresponds to a distance along a normal line direction of the base surface between the surface of the transparent film base 12 and the surface of the upper transparent conductive oxide layer 13b at a metal layer 14-formed portion.

The stacking structure of the transparent electrode layer 11 is appropriately selected in view of, for example, adhesion between the transparent film base 12 and the transparent electrode layer 11, and the kind of a layer (film) stacked on the transparent electrode layer 11. When the stacking structure is selected in view of adhesion, for example, the first stacking structure or the third stacking structure is preferable in the case where adhesion between the transparent film base 12 and the metal layer 14 is higher than adhesion between the transparent film base 12 and the transparent electrode layer 11.

In production of the transparent conductive film, the transparent electrode layer is formed on the transparent film base 12. Preferably, the transparent conductive oxide layer 13 and the metal layer 14 in the transparent electrode layer 11 are formed by a sputtering method. Preferably, sputtering deposition is performed by a roll-to-roll method using a roll-to-roll sputtering apparatus.

The substrate temperature during deposition of the transparent conductive oxide layer and the metal layer by sputtering may be set within a range that the transparent film base 12 exhibits heat resistance, and is preferably 60° C. or lower, more preferably −20° C. or higher and 40° C. or lower. When the substrate temperature is within the range described above, moisture or an organic substance (e.g., oligomer component) is hardly volatilized from the transparent film base 12, so that crystallization of the transparent conductive oxide layer easily progresses. In addition, the resistivity of the transparent conductive oxide layer after crystallization tends to decrease when the substrate temperature is within the range described above.

In sputtering deposition, an inert gas such as an argon or nitrogen gas is introduced into a deposition chamber. Preferably, an oxidizing gas such as an oxygen gas is introduced in addition to the inert gas during deposition of the transparent conductive oxide layer.

The method for patterning the metal layer is not particularly limited. A method in which a patterned metal layer is formed using a mask during deposition, or a method in which a metal layer is deposited over the entire surface and then patterned by etching may be employed. When the metal layer 14 is a copper layer, or a copper alloy layer mainly composed of copper, the metal layer 14 can be easily patterned by etching.

When the metal layer 14 is patterned by etching, etching is performed after deposition of the metal layer 14 on the transparent film base 12 and before formation of other layer on the metal layer 14. In formation of the first stacking structure, the transparent conductive oxide layer 13 and the metal layer 14 are deposited on the transparent film base 12, and then the metal layer 14 is etched. In this configuration, etching is performed after the transparent conductive oxide layer 13 and the metal layer 14 are successively formed over the entire surface of the transparent film base 12, and therefore excellent productivity of the transparent conductive film is attained.

In formation of the second stacking structure, patterning is performed after deposition of the metal layer on the transparent film base 12, and the transparent conductive oxide layer 13 is thereafter deposited on the patterned metal layer (pattern pieces) 14 and the transparent film base 12 exposed between the pattern pieces. In formation of the third stacking structure, the metal layer is patterned after deposition of the lower transparent conductive oxide layer 13a and the metal layer on the transparent film base 12, and the upper transparent conductive oxide layer 13b is thereafter deposited on the patterned metal layer (pattern pieces) 14 and the lower transparent conductive oxide layer 13a exposed between the pattern pieces.

The transparent conductive oxide layer immediately after the deposition is usually an amorphous film when deposited at the above-mentioned substrate temperature. Thus, it is preferable to crystallize the transparent conductive oxide layer by heating after the deposition. For example, the transparent conductive oxide layer 13 including amorphous indium oxide as a main component is crystallized by heating at 80° C. or higher and 150° C. or lower. The transparent conductive oxide layer may be crystallized either before and after deposition of the metal layer and before and after patterning of the metal layer.

The transparent conductive film of the present invention is used as a transparent electrode substrate for a display device such as a display or a touch panel, and suitably used as a transparent electrode substrate particularly for a touch panel. The transparent conductive film is preferably used particularly for a capacitance touch panel because the transparent electrode layer 11 has low resistance.

FIG. 6 is a plan view showing one example of a display device. A bezel 33 is provided on the peripheral edge of the display device 31, and the area inside the bezel 33 is a display region R_{A}. In other words, the display region R_{A} is a region inside the frame of the bezel 33, a region in which operations are performed by touching a screen in a touch panel, and a region in which information is displayed on a screen in a display.

The peripheral edge of the display region R_{A} is a region that is hard to touch by a finger etc. Thus, when the transparent electrode layer 11 of the transparent conductive film satisfies the above-mentioned metal layer coverage ratio and layer thickness in a display area region (display reference area) RB, quality of a region which is touched or viewed by a user can be efficiently improved. Herein, the display area region is a central region of the display region R_{A} which does not include the peripheral edge and which occupies 80% or more of the display region R_{A}.

In formation of a touch panel, lead circuit wiring is formed on the transparent electrode of the transparent conductive film in a non-visible region (outer periphery of display region R_{A}) that is to be covered with the bezel 33. The circuit wiring is formed by, for example, printing of a conductive ink or conductive paste, a dry coating method, a photolithography method. In formation of a display, a thin-film transistor is formed on the transparent conductive film, and a liquid crystal layer or the like is provided thereon.

### EXAMPLES

Hereinafter, the present invention will be described more in detail by showing examples, but the present invention is not limited to these examples.

[Measurement Methods in Examples]

### <Metal Layer Coverage Ratio>

A surface of a transparent electrode layer was observed with a microscope (Model: MF-B1010B manufactured by Mitutoyo Corporation), and the metal layer coverage ratio was calculated from the observed image.

### <Sheet Resistance>

The surface sheet resistance of a transparent electrode layer was measured by four-point probe pressure contact measurement using Low-Resistance Meter LORESTA GP (MCP-T710 manufactured by Mitsubishi Chemical Corporation).

### <Light Transmittance>

The light transmittance was measured using a haze meter (Model: NDH 7000SP manufactured by NIPPON DENSHOKU INDUSTRIES Co., LTD).

### <Warpage>

A transparent conductive film cut to a square having a size of 400 mm×400 mm was placed on a horizontal table with a transparent electrode layer situated on the upper side, and the warpage was measured using a height gauge. The film was rated as being “not warped” when the absolute value of warpage was 30 mm or less, and the film was rated as being “warped” when the absolute value of warpage was more than 30 mm.

[Deposition of Transparent Conductive Oxide Layer]

In Examples and Comparative Examples, indium tin oxide (content of tin oxide: 10% by weight) was used as a target for formation of a transparent conductive oxide layer. In formation of transparent conductive oxide layers in a first stacking structure and a second stacking structure, and an upper transparent conductive oxide layer on a metal layer in a third stacking structure, an ITO underlying layer having a layer thickness of 2 nm was deposited by sputtering under conditions of an oxygen partial pressure of 2×10⁻⁴ Pa, a deposition chamber pressure of 0.2 Pa, a substrate temperature of 0° C. and a power of 4 kW while a mixed gas of oxygen and argon was introduced into an apparatus. An ITO layer was deposited on the underlying layer in the same manner as in the deposition of the underlying layer except that the oxygen partial pressure and the power were changed to 2×10⁻³ Pa and 12 kW, respectively. The layer thickness T of the transparent conductive oxide layer in the first stacking structure and the second stacking structure is the total thickness of the 2 nm-thick underlying layer and the layer deposited on the underlying layer. In the third stacking structure, thickness T_{b} of the upper transparent conductive oxide was 25 nm, which was the total thickness of the 2 nm-thick underlying layer and the layer deposited on the underlying layer.

In the third stacking structure, indium tin oxide (content of tin oxide: 10% by weight) was used as a target for formation of a lower transparent conductive oxide layer immediately below the metal layer. An ITO underlying layer having a layer thickness Tₐ of 5 nm was deposited under conditions of an oxygen partial pressure of 2×10⁻³ Pa, a deposition chamber pressure of 0.2 Pa, a substrate temperature of 0° C. and a power of 12 kW while a mixed gas of oxygen and argon was introduced into an apparatus.

[Deposition and Patterning of Metal Layer]

Copper was used as a target for formation of a metal layer. A copper layer was deposited by sputtering under conditions of a deposition chamber pressure of 0.2 Pa, a substrate temperature of 0° C. and a power of 12 kW while an argon was introduced into a sputtering apparatus. After deposition of the metal layer, patterning was performed by a photolithography method using an iron oxide aqueous solution as an etchant.

When the pattern had a stripe shape, the line width W of the stripe line (linear pattern piece) was 5 and the distance D between stripe lines was set as shown in Table 1. When the pattern had a mesh shape, the line width W of the metal line was 5 μm, the shape of the mesh opening was a square, and the distance D between stripe lines (length of one side of square opening) was set as shown in Table 1. When the pattern had a dot shape, dots having a diameter W of 1 to 7 μm were randomly arranged in such a manner that the value of the metal layer coverage ratio was as shown in Table 1.

[Annealing of Transparent Conductive Oxide Layer]

After deposition of the transparent conductive oxide layer and the metal layer and patterning of the metal layer, heating treatment (annealing) was performed at 120° C. for 3 hours. The transparent electrode layer after heating was observed with a microscope, and the results showed that in Examples and Comparative Examples, the transparent conductive oxide layer was completely crystallized (crystallinity was 100%).

### Examples 1 to 14 and Comparative Example 1

A low-heat-shrinkable polyethylene terephthalate (PET) film having an MD heat shrinkage ratio of almost 0% and a TD heat shrinkage ratio of 0.2% was used as a transparent film base. A transparent electrode layer was formed on the transparent film base to prepare a transparent conductive film. Stacking structure, pattern of the metal layer, width W of the metal layer, pattern distance D of the metal layer, metal line coverage ratio, layer thickness T of the transparent conductive layer, layer thickness M of the metal layer, and maximum layer thickness L of the transparent electrode layer are summarized in Table 1.

In preparation of a transparent conductive film having a first stacking structure, deposition of a transparent conductive oxide layer on a transparent film base, deposition of a metal layer, patterning of the metal layer, and annealing of a transparent conductive oxide were performed in this order. In preparation of a transparent conductive film having a second stacking structure, deposition of a metal layer on a transparent film base, patterning of the metal layer, deposition of a transparent conductive oxide layer, and annealing of a transparent conductive oxide were performed in this order. In preparation of a transparent conductive film having a third stacking structure, deposition of a lower transparent conductive oxide layer on a transparent film base, deposition of a metal layer, patterning of the metal layer, deposition of an upper transparent conductive oxide layer, and annealing of a transparent conductive oxide were performed in this order.

### Comparative Example 2

In Comparative Example 2, a transparent conductive oxide layer having a layer thickness of 500 nm was deposited on a transparent film base, and annealing was then performed to prepare a transparent conductive film which did not include a metal layer (coverage ratio is zero because there is no metal layer).

### Comparative Example 3

In Comparative Example 3, a metal layer was deposited on a transparent film base, and the metal layer was patterned in a mesh shape to prepare a transparent conductive film which did not include a transparent conductive oxide layer.

The configurations of the transparent conductive films in Examples and Comparative Examples, and the results of evaluation of the sheet resistance, light transmittance and warpage of these transparent conductive films are shown in Table 1.

TABLE 1

| | | metal | | | coverage | | | | sheet | light | |
|---|---|---|---|---|---|---|---|---|---|---|---|
| | stacking | layer | W | D | ratio | T | M | L | resistance | transmittance | |
| | configuration | pattern | (μm) | (μm) | (%) | (nn) | (nm) | (nm) | (Ω/sq) | (%) | warpage |
| Example 1 | first | stripe | 5 | 828 | 0.6 | 15 | 70 | 85 | 65 | 87.4 | not warped |
| Example 2 | first | mesh | 5 | 1659 | 0.6 | 15 | 70 | 85 | 62 | 87.4 | not warped |
| Example 3 | first | dot | 1-7 | random | 0.6 | 15 | 70 | 85 | 68 | 87.4 | not warped |
| Example 4 | second | stripe | 5 | 828 | 0.6 | 15 | 70 | 85 | 72 | 87.4 | not warped |
| Example 5 | second | mesh | 5 | 1659 | 0.6 | 15 | 70 | 85 | 70 | 87.4 | not warped |
| Example 6 | second | dot | 1-7 | random | 0.6 | 15 | 70 | 85 | 76 | 87.4 | not warped |
| Example 7 | third | stripe | 5 | 828 | 0.6 | 15 | 70 | 85 | 70 | 87.4 | not warped |
| Example 8 | third | mesh | 5 | 1659 | 0.6 | 15 | 70 | 85 | 70 | 87.4 | not warped |
| Example 9 | third | dot | 1-7 | random | 0.6 | 15 | 70 | 85 | 70 | 87.4 | not warped |
| Example 10 | second | stripe | 5 | 328 | 1.5 | 15 | 70 | 85 | 17 | 86.5 | not warped |
| Example 11 | second | stripe | 5 | 195 | 2.5 | 15 | 70 | 85 | 10 | 86.5 | not warped |
| Example 12 | second | stripe | 5 | 195 | 2.5 | 50 | 200 | 250 | 5 | 86.5 | not warped |
| Example 13 | first | mesh | 5 | 392 | 2.5 | 50 | 150 | 200 | 6 | 86.5 | not warped |
| Example 14 | first | mesh | 5 | 392 | 2.5 | 100 | 100 | 200 | 7 | 86.5 | not warped |
| Comparative | first | mesh | 5 | 192 | 5.0 | 50 | 150 | 200 | 3 | 83.0 | warped |
| Example 1 | | | | | | | | | | | |
| Comparative | — | | | | 0 | 500 | — | 500 | 5 | 68.0 | warped |
| Example 2 | | | | | | | | | | | |
| Comparative | — | mesh | 5 | 659 | 1.5 | — | 200 | 200 | 8 | 88.5 | warped |
| Example 3 | | | | | | | | | | | |

In Examples 1 to 9 where the layer thickness T of the transparent conductive oxide layer was 15 nm, the layer thickness M of the metal layer was 70 nm, and the metal layer coverage ratio was 0.6%, the transparent conductive films had the same light transmittance and almost the same value of sheet resistance even though the stacking configuration and the pattern shape of the metal layer were changed. In other words, a transparent conductive film having a sheet resistance of 80 Ω/sq or less and a light transmittance of 85% or more was obtained in each of Examples 1 to 9, and the obtained transparent conductive film had both high transparency and low resistance, and had no warpage.

In Examples 6, 10 and 11 where the transparent electrode layer had a second stacking structure and included a metal layer patterned in a stripe shape, the light transmittance tended to slightly decrease with an increase in metal layer coverage ratio, while sheet resistance was considerably reduced. The transparent conductive film was not warped even in Examples 10 and 11.

In Example 12 where the layer thickness T of the transparent conductive oxide layer and the layer thickness M of the metal layer were larger as compared to Example 11, surface resistance was lower than that in Example 11. Even though the maximum layer thickness L of the transparent conductive layer was increased to 250 nm, the transparent conductive film was not warped.

In Examples 13 and 14 where the transparent electrode layer had a first stacking structure and included a metal layer pattered in a mesh shape, surface resistance was reduced as in the case of Example 12. The transparent conductive film was not warped even in Examples 13 and 14.

On the other hand, in Comparative Example 1 where the layer thickness of each of the transparent conductive oxide layer and the metal layer was identical to that in Example 13, and the coverage ratio was increased to 5.0%, sheet resistance was lower than that in Example 13, while the light transmittance decreased. The transparent conductive film was warped with an increase in coverage ratio.

When as in Comparative Example 2, the transparent conductive layer is composed of only a transparent conductive oxide, and does not include a metal layer, it is necessary to increase the thickness of the transparent conductive oxide layer to 500 nm for reducing resistance comparable to that in Example 12. Accordingly, the light transmittance considerably decreased, and the transparent conductive film was warped with an increase in layer thickness. This result indicates that when the transparent electrode layer includes only a transparent conductive oxide layer, it is difficult to achieve reduction of resistance, enhancement of transparency and prevention of warpage in a well-balanced manner.

A transparent electrode layer in which the transparent conductive layer does not include a transparent conductive oxide layer, and is composed of only a metal mesh as in Comparative Example 3 has low resistance even though the metal layer coverage ratio is small, so that it is possible to achieve both reduction of resistance and enhancement of transparency. However, in Comparative Example 3, the transparent conductive film was warped. This result suggests that when the transparent conductive oxide layer is provided in contact with the patterned metal layer, stress at the interface between the transparent electrode layer and the film base is relaxed, so that warpage can be suppressed.

An amorphous semiconductor layer composed of an indium-gallium-zinc composite oxide was formed on the metal mesh electrode of the transparent conductive film in Comparative Example 3, and surface charge was measured. There was a difference between charge at a spot where the semiconductor layer was in contact with the metal layer and charge at a spot where the semiconductor layer was not in contact with the metal layer. This result suggests that in a transparent electrode including only a patterned metal layer, an in-plane potential difference occurs, and thus the transparent electrode is not suitable as an electrode for operating a device with in-plane uniformity.

Comparison between Examples and Comparative Examples shows that when the transparent electrode layer includes a transparent conductive oxide layer and a patterned metal layer, and the thickness of the transparent electrode layer and the metal layer coverage ratio are each within a specific range, a transparent conductive film which has both low resistance and high transparency and is inhibited from being warped can be provided.

### DESCRIPTION OF REFERENCE CHARACTERS

11 transparent electrode
12 transparent film base
13 transparent conductive oxide layer
14 metal layer
21, 22, 23 transparent conductive film

1. A transparent conductive film comprising: a transparent film base; and a transparent electrode layer provided on the transparent film base, wherein
the transparent electrode layer includes a transparent conductive oxide layer and a patterned metal layer stacked in contact with each other,
the transparent electrode layer has a maximum layer thickness of 300 nm or less,
the metal layer has a metal pattern width of 1 μm or more and 8 μm or less, and a metal pattern coverage ratio of 0.4% or more and 3.2% or less.

2. The transparent conductive film according to claim 1, wherein the metal layer has a layer thickness of 50 nm or more and 250 nm or less.

3. The transparent conductive film according to claim 1, wherein a pattern shape of the metal layer is a stripe shape, and a distance between metal lines is 30 μm or more and 2000 μm or less.

4. The transparent conductive film according to claim 1, wherein a pattern shape of the metal layer is a mesh shape, and a size of a mesh opening is 30 μm or more and 2000 μm or less.

5. The transparent conductive film according to claim 1, wherein a pattern shape of the metal layer is a dot shape, and a distance between dots is 30 μm or more and 2000 μm or less.

6. The transparent conductive film according to claim 1, wherein the transparent electrode layer includes the transparent conductive oxide layer and the metal layer in this order from a transparent film base side.

7. The transparent conductive film according to claim 1, wherein the transparent electrode layer includes the metal layer and the transparent conductive oxide layer in this order from a transparent film base side.

8. The transparent conductive film according to claim 1, wherein in the transparent electrode layer, the metal layer is encapsulated in the transparent conductive oxide layer.

9. The transparent conductive film according to claim 1, wherein the transparent conductive oxide layer is a crystalline film mainly composed of indium oxide.

10. The transparent conductive film according to claim 1, wherein the metal layer is a copper layer or a copper alloy layer.

11-12. (canceled)

13. A transparent conductive film comprising: a transparent film base; and a transparent electrode layer provided on the transparent film base, wherein
the transparent electrode layer includes a transparent conductive oxide layer and a patterned metal layer stacked in contact with each other,
the transparent electrode layer has a maximum layer thickness of 300 nm or less,
the metal layer has a thickness of between 50 nm-250 nm and comprises a pattern width of between 1 μm-8 μm and a coverage ratio of between 0.4%-3.2%, wherein the transparent conductive oxide layer is arranged between the transparent film and the metal layer.

14. The transparent conductive film according to claim 13, wherein the metal layer comprises a plurality of metal lines spaced apart by 30 μm-2000 μm.

15. The transparent conductive film according to claim 13, wherein the metal layer comprises a mesh pattern having openings of between 30 μm-2000 μm.

16. The transparent conductive film according to claim 13, wherein the metal layer comprises a plurality of dots wherein adjacent spaced dots are spaced apart by a distance of 30 μm-2000 μm.

17. The transparent conductive film according to claim 13, wherein the transparent conductive oxide layer comprise a crystalline film.

18. The transparent conductive film according to claim 17, wherein the crystalline film comprises indium oxide.

19. The transparent conductive film according to claim 13, wherein the metal layer comprises copper or a copper alloy.
